(19) United States
(12) Patent Application Publication
(10) Pub. No.: US 2010/0128512 A1
(43) Pub. Date: May 27, 2010

(54) SEMICONDUCTOR MEMORY DEVICE HAVING CROSS-POINT STRUCTURE

(76) Inventors: Tetsuya Ohnishi, Nara (JP); Syogo Hayashi, Nara (JP)

Correspondence Address: NIXON & VANDERHYE, PC, 901 NORTH GLEBE ROAD, 11TH FLOOR, ARLINGTON, VA, 22203, US

(21) Appl. No.: 12/089,273

(22) PCT Filed: Sep. 27, 2006
(86) PCT No.: PCT/JP2006/319130

§ 371 Date: Apr. 4, 2008

(30) Foreign Application Priority Data
Nov. 2, 2005 (JP) 2005-319882

(51) Int. Cl. G11C 11/22; G11C 11/00

(52) U.S. Cl. 365/145; 365/148; 365/158

(57) ABSTRACT

A semiconductor memory device having a cross-point structure comprising a plurality of first electrode wirings extending in the same direction, a plurality of second electrode wirings intersecting with the first electrode wirings, and memory materials for storing data at the intersection points of the first and second electrode wirings has a problem that an effective voltage applied to the memory material fluctuates in a memory cell array due to the voltage drop caused by the wiring resistance of each electrode wiring. The sum of the wiring resistance of the first electrode wiring to a certain intersection point and the wiring resistance of the second electrode wiring to the certain intersection point is substantially constant at any intersection point, and the load resistors for adjusting the fluctuation of the electrode wiring resistances in a memory cell array are connected at least either one of the first and second electrode wirings.

### CROSS-REFERENCE TO RELATED APPLICATIONS

This application is a National Phase filing under 35 U.S.C. §371 of International Application No. PCT/JP2006/319130 filed on Sep. 27, 2006, and which claims priority to Japanese Patent Application No. 2005-319882 filed on Nov. 2, 2005.

### TECHNICAL FIELD

The present invention relates to a semiconductor memory device having a cross-point structure comprising a plurality of first electrode wirings extending in the same direction, a plurality of second electrode wirings intersecting with the first electrode wirings, and memory materials for storing data at the intersection points between the first electrode wirings and the second electrode wirings.

### BACKGROUND ART

In general, according to a semiconductor memory device such as a DRAM, NOR type flash, and FeRAM, a memory cell comprises a memory element for storing data and a selection transistor for selecting the memory element. Meanwhile, according to a memory cell having a cross-point structure, only a memory material is disposed at an intersection point (cross point) between a bit line and a word line without using the selection transistor. According to the memory cell array having the cross-point structure, since data stored at the intersection point between the selected bit line and the selected word line is directly read without using the selection transistor, although the problem is that an operation speed is delayed and current consumption is increased due to a parasitic current from an unselected memory cell connected to the same bit line or word line as that of a selected memory cell, it attracts an attention because large capacity can be implemented due to its simple structure. Thus, a semiconductor memory device comprising cross-point structured memory cells has been proposed as a MRAM (magnetoresistive memory), a FeRAM (ferroelectric memory), and a RRAM (resistor memory). In addition, the MRAM is a kind of a nonvolatile memory that stores data using a ferromagnetic tunneling magneto resistance (TMR) effect of a memory material of a memory cell, that is, resistance change due to a difference in a magnetization direction. The FeRAM is a kind of a nonvolatile memory that stores data using ferroelectric characteristics of a memory material of a memory cell, that is, a difference in residual polarization of an electric field. In addition, the RRAM is a kind of a nonvolatile memory that stores data using an electric resistance change effect of an electric field.

For example, an MRAM comprising a memory cell constitution having a cross-point structure is disclosed in FIG. 2 of a patent document 1, a FeRAM comprising a memory cell constitution having a cross-point structure is disclosed in FIG. 2 of a patent document 2, and a RRAM comprising a memory cell constitution having a cross-point structure is disclosed in FIG. 6 of a patent document 3.

FIG. 10 is a schematic block diagram showing one embodiment of a semiconductor memory device having a cross-point structure. A semiconductor memory device 500 comprises a control circuit 506, a read circuit 505, a bit line decoder 502, a word line decoder 503, and a voltage pulse generation circuit 504 as peripheral circuits of a memory cell array 501.

The control circuit 506 controls programming, erasing and reading of the memory cell array 501. Data is stored in a specific memory cell in the memory cell array 501 according to an address signal, and the data is outputted to an external device through the read circuit 505. The control circuit 506 controls the bit line decoder 502, the word line decoder 503, and the voltage pulse generation circuit 504 based on the address signal, data inputted at the time of programming, and a control input signal to control the reading, programming and erasing operations of the memory cell array 501. The control circuit 506 functions as a general address buffer circuit, data input/output buffer circuit, and a control input buffer circuit although they are not shown in FIG. 10.

The word line decoder 503 is connected to word lines of the memory cell array 501 and selects a word line of the memory cell array 501 according to the address signal, and the bit line decoder 502 is connected to bit lines of the memory cell array 501 and selects a bit line of the memory cell array 501 according to the address signal.

The voltage pulse generation circuit 504 generates voltages applied to the bit line and the word line for the reading, programming and erasing operations of the memory cell array 501. At the time of programming operation, each voltage for the bit lines and the word lines is set so that a voltage pulse having a voltage higher than a voltage required for the programming is applied only to between the bit line and the word line of the memory material of the memory cell selected by the address signal, and applied to the selected and unselected bit lines and the selected and unselected word lines from the voltage pulse generation circuit 504 through the bit line decoder 502 and the word line decoder 503. The programming voltage pulse is applied to the memory material of the selected memory cell to be programmed while its applying time is controlled by a pulse width set by the control circuit 506.

FIG. 11 is an equivalent circuit diagram showing a memory cell array 601 as an example of the RRAM. The memory cell array 601 in this example comprises M bit lines and N word lines to constitute M×N memory cells in which a variable resistor Rᵥₑᵣ as a memory material is disposed at the intersection point between each bit line and each word line. The bit lines B1, B2, B3, . . . , BM and the word lines W1, W2, W3, . . . , WN are electrically connected to a bit line decoder 602 and a word line decoder 603, respectively, and a voltage suitable for each of reading, programming, and erasing operations is applied to each wiring.

As the memory material, a ferroelectric material can be used in the case of the FeRAM (ferroelectric memory) and a film having the TMR effect can be used in the case of the MRAM (magnetoresistive memory) other than the variable resistor Rᵥₑᵣ.

Patent document 1 Japanese Unexamined Patent Publication No. 2001-273757
Patent document 2 Japanese Unexamined Patent Publication No. 2003-288784
Patent document 3 Japanese Unexamined Patent Publication No. 2003-68983

### DISCLOSURE OF THE INVENTION

### Problems to be Solved by the Invention

A problem of a conventional semiconductor memory device having a cross-point structure will be described taking a 4×4 simple memory cell array shown in FIG. 12 to be easily understood. In addition, the RRAM comprising the variable resistor Rᵥₑᵣ as a memory material is used similar to FIG. 11.

The memory cell array 701 comprises four bit lines (B1, B2, B3 and B4) connected to a bit line decoder 702, four word lines (W1, W2, W3 and W4) connected to a word line decoder 703, and 4×4 memory cells having variable resistors at the intersection points between the bit lines and the word lines.

FIG. 13 is a schematic plan view showing an element structure as one configuration of the memory cell array. The memory cell array comprises upper electrode wirings 36 serving as the bit lines and lower electrode wirings 34 serving as the word lines intersecting with the upper electrode wirings 36. The upper electrode wiring 36 and the lower electrode wiring 34 are connected to a bit line decoder (not shown) and a word line decoder (not shown) at their ends through metal wirings 31 and 32, respectively.

In addition, FIG. 14A is a schematic sectional view taken along line S₉-S₉ in FIG. 13 and FIG. 14B is a schematic sectional view taken along line S₁₀-S₁₀ in FIG. 13. A variable resistor 35 serving as a memory material is disposed between the upper electrode wiring 36 and the lower electrode wiring 34 formed on a base substrate 33. In addition, the upper electrode wiring 36 and the lower electrode wiring 34 are electrically connected to the bit line decoder and the word line decoder by the metal wirings 31 and 32 through contacts 37 provided their ends, respectively.

Here, it is to be noted that even when the upper electrode wiring 36 and the lower electrode wiring 34 are a conductive material having low resistance, they have wiring resistance to some extent. Therefore, the wiring resistance of the upper and lower electrode wirings are superimposed in the memory cells at the intersection points positioned further away from the bit line decoder and the word line decoder.

Thus, as shown in FIG. 12, when it is assumed that a wiring resistance value of the upper electrode wiring 36 as the bit line across one intersection interval is R_{B}, a wiring resistance value of the lower electrode wiring 34 as the word line across one intersection interval is R_{W}, coordinates of a cell at the intersection point between a bit line Bx and a word line Wy is expressed by (x, y), and a wiring resistance value of the cell at (1, 1) closest to the bit line decoder and the word line decoder is set to a reference value (=0), the relative increase of the wiring resistance at each intersection point from the reference cell at (1, 1) is shown in FIG. 15.

More specifically, there is no increase in resistance value of the upper electrode wiring 36 as the bit line 132 in the cell at (2, 1), since the cell is positioned closest to the bit line decoder 702 similar to the reference cell at (1, 1). Meanwhile, the resistance value of the lower electrode wiring 34 as the word line W1 is increased by the resistance value R_{W} across one intersection interval from the value of the reference cell at (1, 1). Therefore, the relative increase of the resistance value of the cell at that point is R_{W} in total.

Similarly, regarding the increase of the wiring resistance of the cell at (1, 2), since only the resistance of the upper electrode wiring 36 as the bit line B2 across one intersection interval is added, the relative increase of the wiring resistance value is R_{B}.

In addition, the relative increase of the wiring resistance value of the cell at (4, 4) is 3R_{W}+3R_{B} in total, since the resistance across three intersection intervals of the upper electrode wiring 36 and the resistance across three intersection intervals of the lower electrode wiring 34 are added. Therefore, as shown in FIG. 15, the wiring resistance values fluctuate in the 4×4 memory cells as follows.

0 to 3R_{W}+3R_{B} (Formula 1)

In general, in the case of the N×N memory cell, since the wiring resistance of the cell at (N, N) positioned furthest apart from the bit line decoder and the word line decoder is increased by a resistance value across (N−1) intersection intervals from that of the reference cell at (1, 1) along the upper electrode wiring 36 and the lower electrode wiring 34, the wiring resistance values fluctuate as follows.

0 to (N−1)×R_{W}+(N−1)×R_{B} (Formula 2)

Since the resistance of the electrode wiring causes voltage drop along the upper and lower electrode wirings, the operation voltage drops at the time of reading, programming and erasing operations. In other words, since the effective voltage applied to the variable resistor as the memory material substantially drops along the upper and lower electrode wirings, data isolation characteristics at the time of reading, programming and erasing operations deteriorate.

Here, even when the upper electrode wiring 36 and the lower electrode wiring 34 are formed of a material having as small specific resistance as possible, since number of elements (that is, N in the formula 2) connected to the bit line and the word line is increased with the miniaturization and high integration thereof, the problem becomes evident as the capacity of the semiconductor memory device is increased.

In order to improve the above problem if only a little, although there is a method in which metal wirings from the bit line decoder and the word line decoder are connected from both ends of the bit line and the word line of the memory cell array, and the above resistance fluctuation can be reduced to half, the method does not solve the above problem essentially. In addition, although there is a method for preventing the voltage drop due to the upper and lower electrode wirings by providing connection parts connecting the upper electrode wiring or the lower electrode wiring to the bit line decoder or the word line decoder every a few cells in the memory cell array, with a multilayered metal wiring having small resistivity, this method needs many connection parts along the upper and lower electrode wirings to compensate the increase in number of the elements, and as a result the area of the memory cell array is increased and the process becomes complicated because of forming the multilayered metal wiring.

In addition, it is preferable for the RRAM or the FeRAM in this example that a noble metal material is used as its electrode material in some cases. Since the noble metal has higher resistivity (that is, R_{W} or R_{B} in the formula 2) than that of a general metal wiring material such as Al, Cu and the like, the memory material in this case has a more serious problem.

In view of the above problems, it is an object of the present invention to provide a semiconductor memory device having a cross-point structure comprising a plurality of first electrode wirings extending in the same direction, a plurality of second electrode wirings intersecting with the first electrode wirings, memory materials for storing data at intersection points of the first electrode wirings and the second electrode wirings, in which increase of wiring resistance at the first electrode wiring or second electrode wiring is uniform in the memory cell array, an effective voltage applied to the memory material at the time of reading, programming, or erasing operation is kept constant with respect to any cell in the memory cell array, there is less fluctuation, and data isolation characteristics are superior.

### Means for Solving the Problems

In order to attain the above object, a semiconductor memory device having a cross-point structure according to the present invention comprises a plurality of first electrode wirings extending in the same direction, a plurality of second electrode wirings intersecting with the first electrode wirings, memory materials for storing data at intersection points of the first electrode wirings and the second electrode wirings, in which the sum of the wiring resistance value of the first electrode wiring to a certain intersection point and the wiring resistance value of the second electrode wiring to the certain intersection point substantially shows a constant value at any intersection point.

In addition, a semiconductor memory device having a cross-point structure in the present invention comprises a plurality of first electrode wirings extending in the same direction, a plurality of second electrode wirings intersecting with the first electrode wirings, memory materials for storing data at intersection points of the first electrode wirings and the second electrode wirings, in which load resistors for allowing the sum of the wiring resistance value of the first electrode wiring to a certain intersection point and the wiring resistance value of the second electrode wiring to the certain intersection point to show a constant value at any intersection point are connected to at least either one of the plurality of first electrode wirings and the plurality of second electrode wirings.

In addition, a semiconductor memory device having a cross-point structure in the present invention comprises a plurality of first electrode wirings extending in the same direction, a plurality of second electrode wirings intersecting with the first electrode wirings, memory materials for storing data at intersection points of the first electrode wirings and the second electrode wirings, in which a memory cell array is formed by disposing the memory materials at the intersection points of the plurality of first electrode wirings and the plurality of second electrode wirings, and load resistors for adjusting the resistance value of the electrode wiring are connected to at least either one of the plurality of first electrode wirings and the plurality of second electrode wirings outside the memory cell array.

In addition, according to the semiconductor memory device having the cross-point structure in the present invention, the load resistors have resistance values sequentially differentiated in stages between the first electrode wirings or the second electrode wirings or both.

Furthermore, according to the semiconductor memory device having the cross-point structure in the present invention, the resistance values of the load resistors connected to the plurality of first electrode wirings are sequentially differentiated in stages between the load resistors by a value substantially equal to the wiring resistance value of the second electrode wiring across one intersection interval in an extending direction of the second electrode wiring intersecting with the first electrode wiring.

Furthermore, according to the semiconductor memory device having the cross-point structure in the present invention, the resistance values of the load resistors connected to the plurality of second electrode wirings are sequentially differentiated in stages between the load resistors by a value substantially equal to the wiring resistance value of the first electrode wiring across one intersection interval in an extending direction of the first electrode wiring intersecting with the second electrode wiring.

In addition, according to the semiconductor memory device having the cross-point structure in the present invention, the load resistor comprises a part of the first electrode wiring or the second electrode wiring.

Furthermore, according to the semiconductor memory device having the cross-point structure in the present invention, the wiring lengths of the first electrode wirings are differentiated between the first electrode wirings, or the wiring lengths of the second electrode wirings are differentiated between the second electrode wirings.

Still furthermore, according to the semiconductor memory device having the cross-point structure in the present invention, when it is assumed that the number of the first electrode wirings is M is a natural number), a length of one intersection interval in the extending direction of the first electrode wiring is L₁, a wiring resistance value of the first electrode wiring across one intersection interval is R_{B}, a wiring resistance value of the second electrode wiring across one intersection interval in the extending direction of the second electrode wiring is R_{W}, the wiring lengths of the plurality of first electrode wirings are sequentially differentiated in stages between the first electrode wirings by a length of (m−1)×L₁×(R_{W}/R_{B}), wherein m=1, 2, 3, . . . , M.

Still furthermore, according to the semiconductor memory device having the cross-point structure in the present invention, when it is assumed that the number of the second electrode wirings is N (N is a natural number), a length of one intersection interval in the extending direction of the second electrode wiring is L₂, a wiring resistance value of the second electrode wiring across one intersection interval is R_{W}, a wiring resistance value of the first electrode wiring across one intersection interval in the extending direction of the first electrode wiring is R_{B}, the wiring lengths of the plurality of second electrode wirings are sequentially differentiated in stages between the second electrode wirings by a length of (n−1)×L₂×(R_{B}/R_{W}), wherein n=1, 2, 3, . . . , N.

In addition, a semiconductor memory device having a cross-point structure in the present invention comprises a memory cell array having a plurality of first electrode wirings extending in the same direction, a plurality of second electrode wirings intersecting with the first electrode wirings, and memory materials for storing data at the intersection points between the first electrode wirings and the second electrode wirings, a bit line decoder, a word line decoder, and a voltage pulse generation circuit for applying an operation voltage to a certain memory cell in the memory cell array, and further comprises load resistors connected to at least either one of the first electrode wirings and the second electrode wirings and having resistance values differentiated sequentially in stages between the first electrode wirings or the second electrode wirings or both, in which the load resistors allow the sum of a parasitic resistance value from the voltage pulse generation circuit to a certain intersection point through the first electrode wiring and a parasitic resistance value from the voltage pulse generation circuit to the certain intersection point through the second electrode wiring to show a substantially constant value at any intersection point.

Still furthermore, according to the semiconductor memory device having the cross-point structure in the present invention, the memory medium for storing data has ferroelectric characteristics.

Still furthermore, according to the semiconductor memory device having the cross-point structure in the present invention, the memory material for storing data has ferromagnetic tunneling magneto resistance effect.

Still furthermore, according to the semiconductor memory device having the cross-point structure in the present invention, the memory material for storing data is formed of a variable resistor material.

In addition, the term “the substantially constant value” used in this specification means not only completely a constant value but also a roughly constant value within a small range.

### EFFECT OF THE INVENTION

According to the semiconductor memory device having the cross-point structure in the present invention, since the sum of the wiring resistance value of the first electrode wiring to a certain intersection point and the wiring resistance value of the second electrode wiring to the certain intersection point in the memory cell array shows a substantially constant value at any intersection point, the voltage drop to the certain intersection point due to the electrode wiring resistance is uniform, so that there is almost no fluctuation in effective operation voltage applied to the memory material positioned at each intersection point in the memory cell array. Therefore, the semiconductor memory device having the cross-point structure in the present invention is superior in data isolation characteristics at the time of the reading, programming and erasing operations.

In addition, according to the semiconductor memory device having the cross-point structure in the present invention, since the load resistors for adjusting the fluctuation of the electrode wiring resistance value in the memory cell array are connected to at least either one of the first electrode wirings and the second electrode wirings, there is almost no fluctuation in effective operation voltage applied to the memory material positioned at each intersection point in the memory cell array.

### BRIEF DESCRIPTION OF THE DRAWINGS

FIG. 1 is an equivalent circuit diagram showing M×N memory cell array of a semiconductor memory device having a cross-point structure according to the present invention;

FIG. 2 is an equivalent circuit diagram showing a 4×4 memory cell array according to a first embodiment of the present invention;

FIG. 3 is a view showing a relative wiring resistance value in each cell of the 4×4 memory cell array according to the first embodiment of the present invention;

FIG. 4 is a schematic plan view showing a 4×4 memory cell array according to a second embodiment of the present invention;

FIG. 5A is a schematic sectional view taken along a line S₁-S₁ in FIG. 4, FIG. 5B is a schematic sectional view taken along a line S₂-S₂ in FIG. 4, FIG. 5C is a schematic sectional view taken along a line S₃-S₃ in FIG. 4, and FIG. 5D is a schematic sectional view taken along a line S₄-S₄ in FIG. 4;

FIG. 6A is a schematic sectional view taken along a line S₅-S₅ in FIG. 4, FIG. 6B is a schematic sectional view taken along a line S₆-S₆ in FIG. 4, FIG. 6C is a schematic sectional view taken along a line S₇-S₇ in FIG. 4, and FIG. 6D is a schematic sectional view taken along a line S₈-S₈ in FIG. 4;

FIG. 7A is a schematic sectional view taken along a bit line B1 of a 4×4 memory cell array according to a third embodiment of the present invention, FIG. 7B is a schematic sectional view taken along a bit line B4 thereof, FIG. 7C is a schematic sectional view taken along a word line W1 thereof, and FIG. 7D is a schematic sectional view taken along a word line W4 thereof;

FIG. 8 is a view showing a relative wiring resistance value at each cell of a 10×4 memory cell array according to a fourth embodiment of the present invention;

FIG. 9 is a view showing a relative wiring resistance value at each cell of a 8×8 memory cell array according to a fifth embodiment of the present invention;

FIG. 10 is a schematic block diagram showing a semiconductor memory device having a cross-point structure;

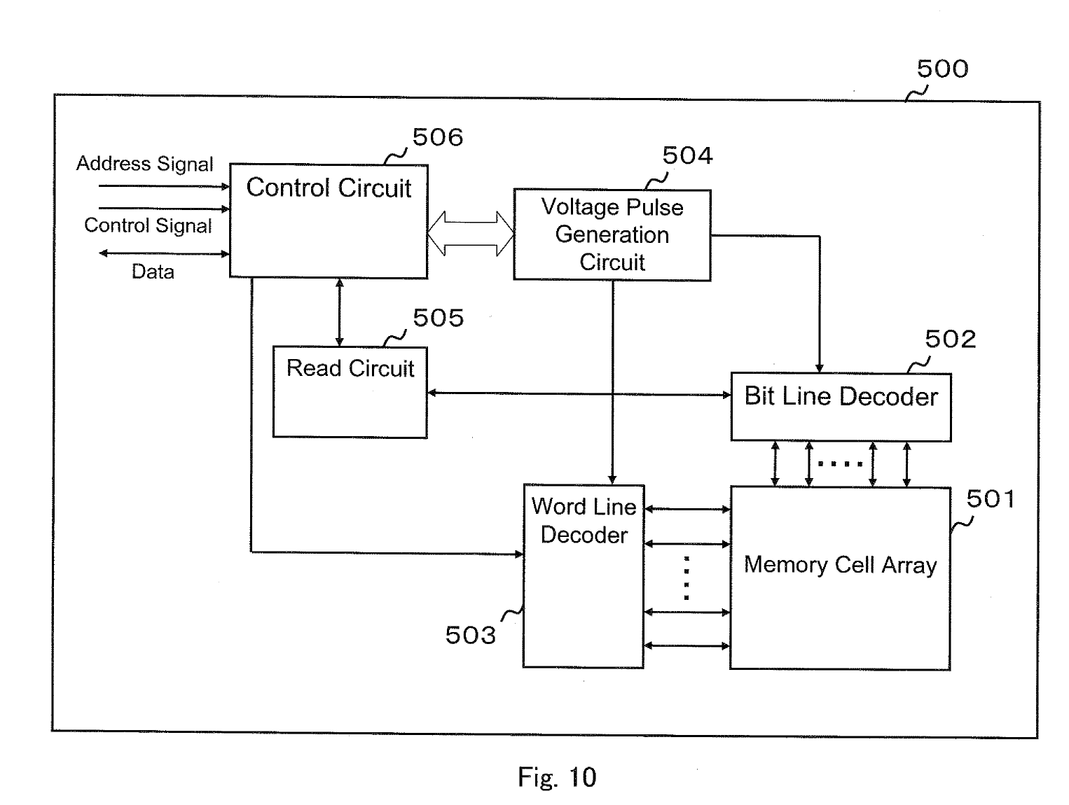

FIG. 11 is an equivalent circuit diagram showing a M×N memory cell array of a conventional semiconductor memory device having a cross-point structure;

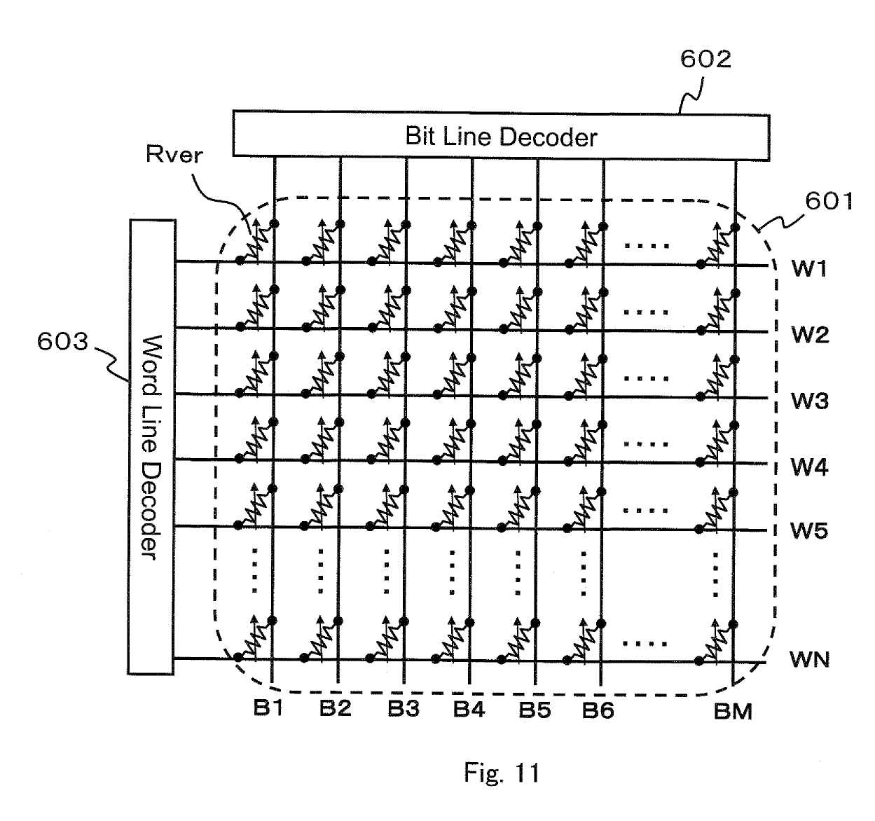

FIG. 12 is an equivalent circuit diagram showing a conventional 4×4 memory cell array;

FIG. 13 is a schematic plan view showing the conventional 4×4 memory cell array;

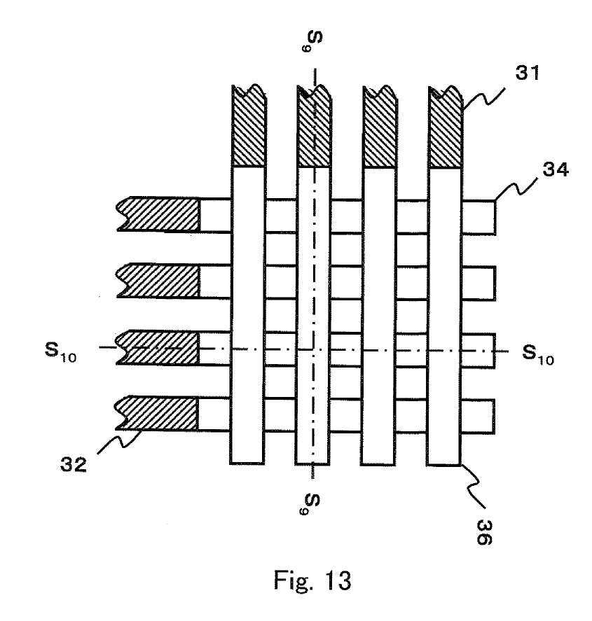

FIG. 14A is a schematic sectional view taken along a line S₉-S₉ in FIG. 13, and FIG. 14B is a schematic sectional view taken along a line S₁₀-S₁₀ in FIG. 13; and

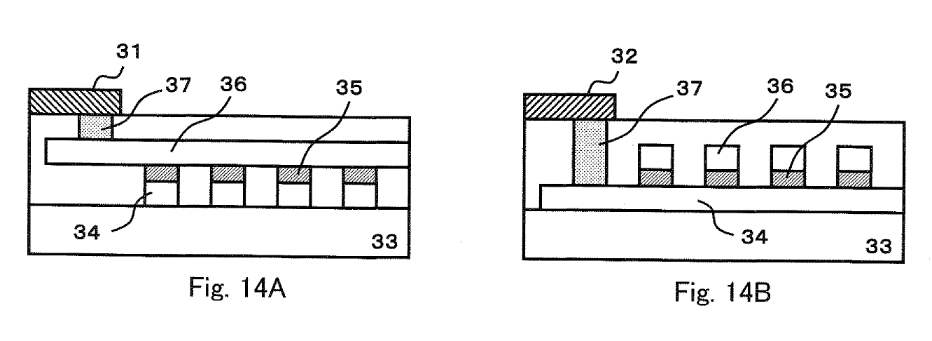

FIG. 15 is a view showing a relative wiring resistance value at each cell of the conventional 4×4 memory cell array.

### EXPLANATION OF REFERENCES

11, 12, 21, 22, 31, 32 Metal wiring
13, 23, 33 Base substrate
14, 24, 34 Lower electrode wiring
15, 25, 35, Rᵥₑᵣ Variable resistor
16, 26, 36 Upper electrode wiring
17, 27, 37 Contact
28, R_{X1}, R_{X2}, . . . , R_{XM}, R_{Y1}, R_{Y2}, . . . , R_{YN} Load resistor
101, 201, 501, 601, 701 Memory cell array
102, 202, 302, 402, 502, 602, 702 Bit line decoder
103, 203, 303, 403, 503, 603, 703 Word line decoder
500 Semiconductor memory device
504 Voltage pulse generation circuit
505 Read circuit
506 Control circuit
B1, B2, . . . , Bx, . . . , BM Bit line
W1, W2, . . . , Wy, . . . , WM Word line

### BEST MODE FOR CARRYING OUT THE INVENTION

Embodiments of the present invention will be described in detail with reference to the drawings hereinafter.

### First Embodiment

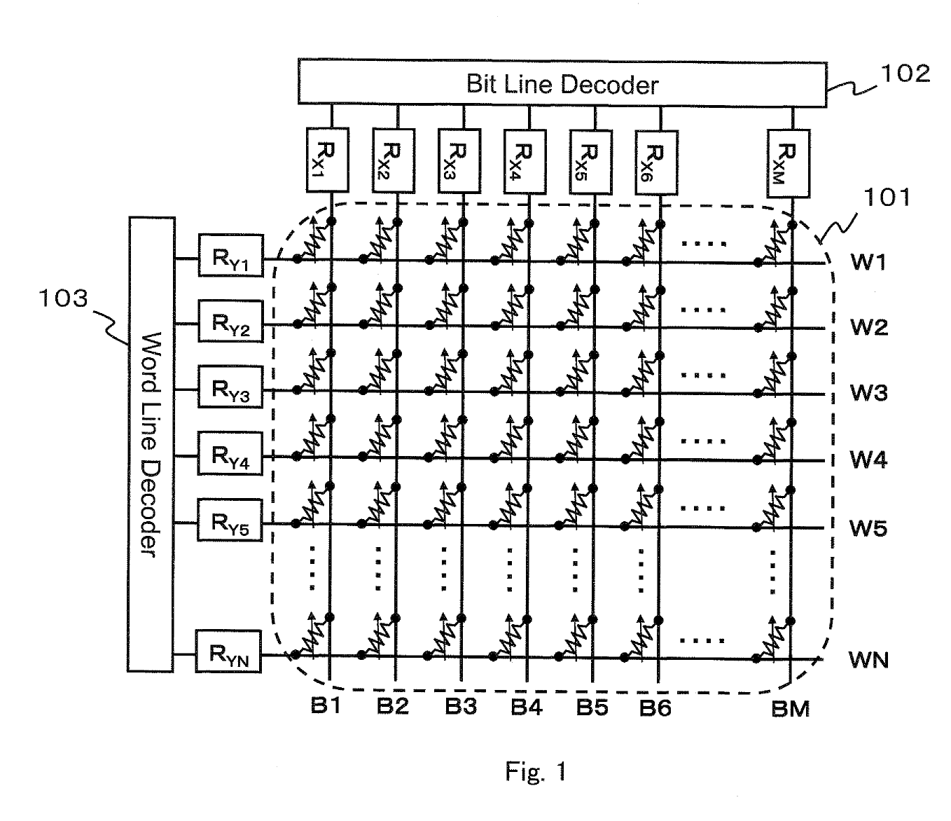

FIG. 1 is an equivalent circuit diagram showing a semiconductor memory device having a cross-point structure according to the present invention. According to the semiconductor memory device having the cross-point structure, load resistors R_{X1}, R_{X2}, . . . , R_{XM}, and R_{Y1}, R_{Y2}, . . . , R_{YN} to adjust the fluctuation in wiring resistance in a memory cell array to reduce it are disposed between bit lines B1, B2, B3, . . . , BM (corresponding to one of first electrode wirings and second electrode wirings) in a memory cell array 101 having M×N memory cells and a bit line decoder 103, and between word lines W1, W2, W3, . . . , WN (corresponding to the other one of the first electrode wirings and second electrode wirings) intersecting with the bit lines and a word line decoder 102, that is, they are disposed on the bit lines and the word lines outside the memory cell array, respectively.

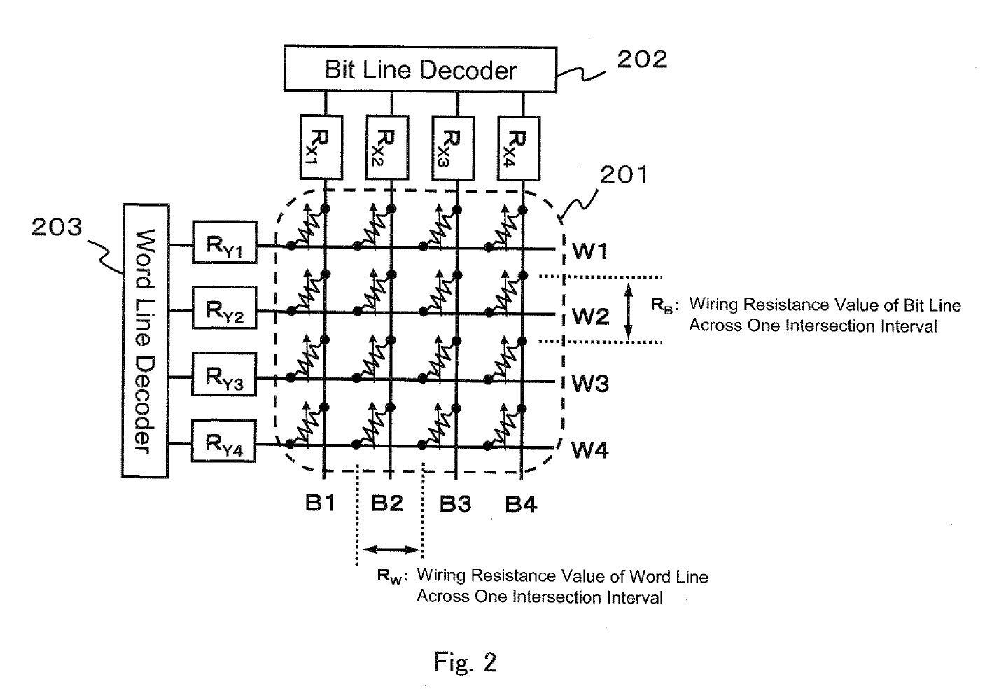

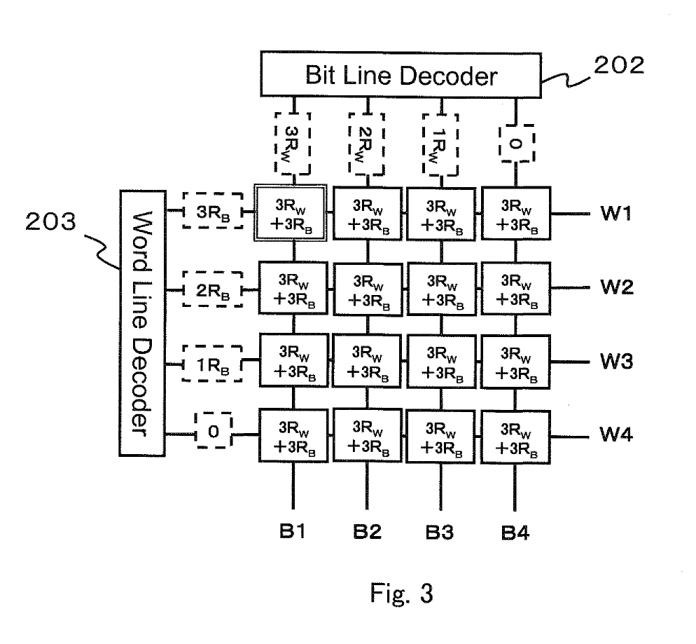

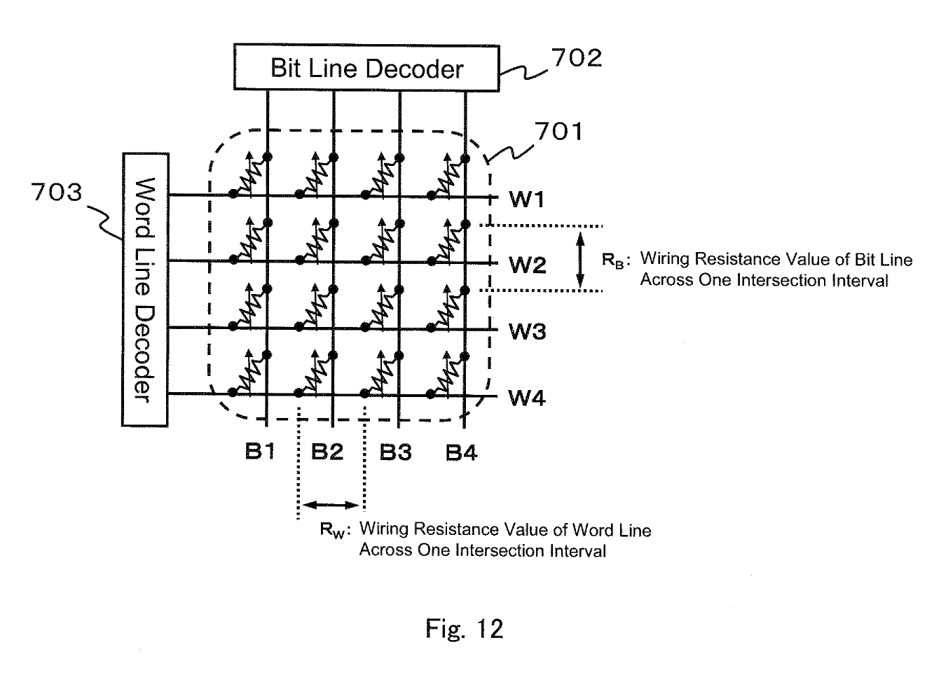

In order to make it clear how much the fluctuation in the wiring resistance can be reduced by the present invention, similar to FIG. 12, a description will be made with a simple 4×4 memory cell array with reference to FIGS. 2 and 3. In addition, it is also assumed that a wiring resistance value of the bit line across one intersection interval is R_{B}, and a wiring resistance value of the word line across one intersection interval is R_{W}.

FIG. 2 is an equivalent circuit diagram showing a 4×4 memory cell array according to a first embodiment of the present invention. Load resistors R_{X1}, R_{X2}, R_{X3}, and R_{X4}, and R_{Y1}, R_{Y2}, R_{Y3}, and R_{Y4} that are characteristic of the present invention are provided between a bit line decoder 202 and a word line decoder 203 through the memory cell array, respectively.

FIG. 3 is an example in which each load resistor value is set such that the relative increase in the wiring resistance in the 4×4 memory cell array 201 shown in FIG. 2 shows a constant value. That is, R_{X1}=3R_{W}, R_{X2}=2R_{W}, R_{X3}=R_{W}, R_{X4}=0, R_{Y1}=3R_{B}, R_{Y2}=2R_{B}, R_{Y3}=R_{B}, and R_{Y4}=0.

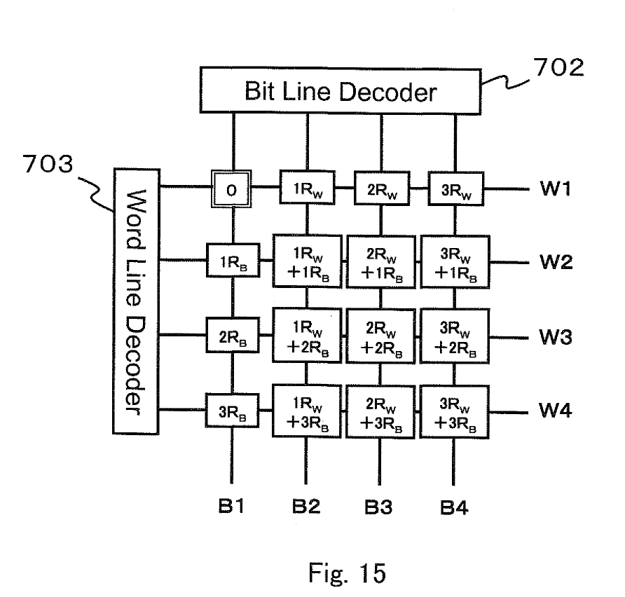

The wiring resistance value of a reference cell at (1, 1) positioned closest to the bit line decoder 202 and the word line decoder 203 is increased by 3R_{W}+3R_{B} due to the newly added load resistors R_{X1} and R_{Y1} as compared with that of the conventional reference cell shown in FIG. 15. According to this embodiment, this is set as a reference value (=3R_{W}+3R_{B}).

Regarding the increase of the wiring resistance of a cell at (2, 1), the increase of the resistance value by the load resistor connected to the bit line B2 is smaller than that of the reference cell at (1, 1) by R_{W}. Meanwhile, since the resistance value with respect to the word line W1 is increased from that of the reference cell at (1, 1) by the resistance value R_{W} of the word line across one intersection interval, the relative increase of the wiring resistance value of the cell positioned at the above point comes out the same as that of the reference cell at (1, 1) as a result.

Similarly, regarding the cell at (1, 2), since the resistance value of the load resistor of the word line W2 is smaller than that of the reference cell at (1, 1) by R_{B} and the resistance value with respect to the bit line is increased by the resistance value R_{B} of the bit line across one intersection interval, the value comes out the same as the reference cell at (1, 1).

In addition, regarding the cell at (4, 4), while the resistance is increased by three intersection intervals of the bit line B4, the resistance value of the load resistor of the word line W4 is smaller than that of the reference cell at (1, 1) by 3R_{B}, the resistance value is the same as that of the reference cell at (1, 1). Similarly, since the increase in resistance value across the intersection intervals of the word line W4 and the decrease in resistance value of the load resistor of the bit line B4 come out even, the total increase of the wiring resistance of the bit line B4 and the word line W4 is equal to that of the reference cell at (1, 1).

Therefore, as shown in FIG. 3, the relative increase of the wiring resistance is constantly 3R_{W}+3R_{B} over all of the 4×4 memory cells, so that the conventional problem of the fluctuation in resistance value can be solved.

### Second Embodiment

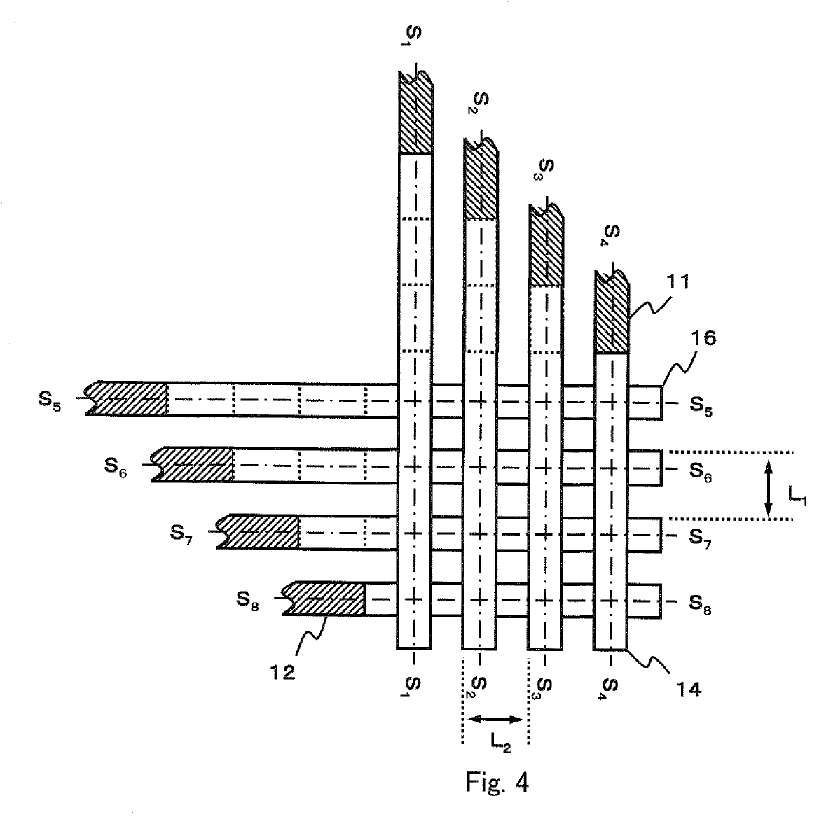

According to a semiconductor memory device having a cross-point structure in a second embodiment of the present invention, specific means for implementing the first embodiment is shown. That is, in order to providing a 4×4 memory cell array as shown in FIG. 2, as shown in FIG. 4, the lengths of upper electrode wirings 14 as bit lines and lower electrode wirings 16 as word lines are elongated toward a bit line decoder and a word line decoder to form a load resistor.

Referring to FIG. 4, when it is assumed that a length of one intersection interval of the upper electrode wirings 14 as the bit lines is L₁, and a length of one intersection interval of the lower electrode wirings 16 as the word lines is L₂, wiring resistance values of the upper electrode wiring 14 and the lower electrode wiring 16 per unit length are expressed by the following formulas 3 and 4, respectively.

R_{B}/L₁ (Formula 3)

R_{W}/L₂ (Formula 4)

Here, when a bit line B3 (S₃-S₃ line) is elongated toward the bit line decoder by a length provided by dividing the resistance value R_{W} by the wiring resistance value (R_{B}/L₁) per unit length shown in the formula 3, as shown in formula 5, the resistance value of the load resistor connected to a bit line B3 becomes 1R_{W} as shown in FIG. 3.

R_{W}/(R_{B}/L₁)=L₁×(R_{W}/R_{B}) (Formula 5)

Similarly, a bit line 132 (S₂-S₂ line) and a bit line B1 (S₁-S₁ line) are to be elongated toward the bit line decoder by 2×L₁×(R_{W}/R_{B}) and 3×L₁×(R_{W}/R_{B}), respectively. In addition, since it is not necessary to increase the resistance values of a bit line B4 (S₄-S₄ line) by the load resistor, the length of it is not elongated.

Meanwhile, regarding a word line W3 (S₇-S₇ line), the load resistor shown in FIG. 3 can be implemented by elongating the word line W3 toward the word line decoder by a length provided by dividing the resistance value R_{B} by the wiring resistance value (R_{W}/L₂) per unit length shown in the formula 4, as shown in formula 6.

R_{B}/(R_{W}/L₂)=L₂×(R_{B}/R_{W}) (Formula 6)

Similarly, a word line W2 (S₆-S₆ line) and a word line W1 (S₅-S₅ line) are to be elongated in the direction of the word line by 2×L₂×(R_{B}/R_{W}) and 3×L₂×(R_{B}/R_{W}), respectively. In addition, since it is not necessary to increase the resistance value of a word line W4 (S₈-S₈ line) by the load resistor, the length of it is not elongated.

According to this embodiment, since the load resistor is formed of the same material as the upper or lower electrode wiring materials, the upper electrode wirings as the bit lines are just elongated sequentially by the length defined by the formula 5, and the lower electrode wirings as the word lines are just elongated sequentially by the length defined by the formula 6. Here, when R_{B}=R_{W}, the lengths in the formulas 5 and 6 are L₁ and L₂, respectively, so that when the wiring resistance value across one intersection interval in the direction of the upper electrode wiring is equal to that in the direction of the lower electrode wiring, the upper electrode wirings and the lower electrode wirings are just elongated sequentially in stages by each length of one intersection interval in their extending direction, respectively.

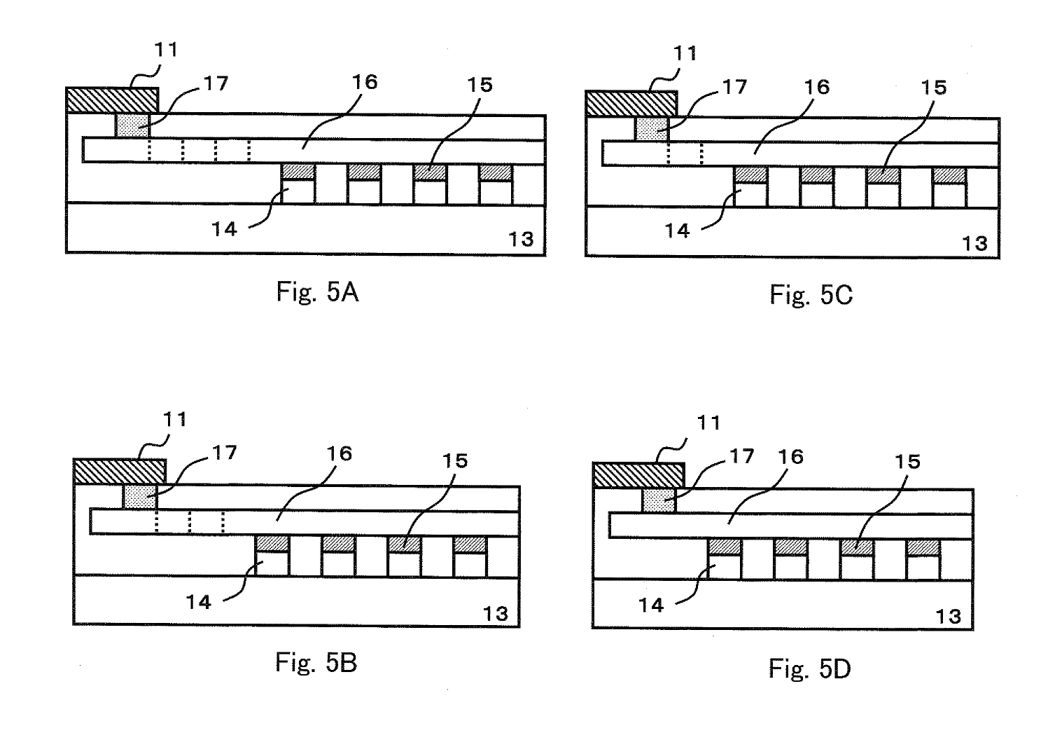

FIGS. 5A to 5D are schematic sectional views taken along lines S₁-S₁ to S₄-S₄ in FIG. 4, respectively. A variable resistor 15 as a memory material is provided between the upper electrode wiring 16 and the lower electrode wiring 14 formed on a base substrate 13, and the upper electrode wiring 16 is connected to the bit line decoder (not shown) by a metal wiring 11 through a contact 17. The base substrate 13 may be a substrate on which a peripheral circuit and the like constituting the semiconductor memory device is formed as needed, and it is preferable that the surface is formed of an insulating film for the lower electrode wirings 14. The length of the upper electrode wirings 16 from the end of the cell closest to the bit line decoder to the contact 17 are sequentially elongated by the length defined in the formula 5 as shown in FIGS. 5D, 5C, 5B, and 5A, respectively. In addition, the increased lengths of the upper electrode wirings 16 are shown by dotted lines in FIGS. 4 and 5.

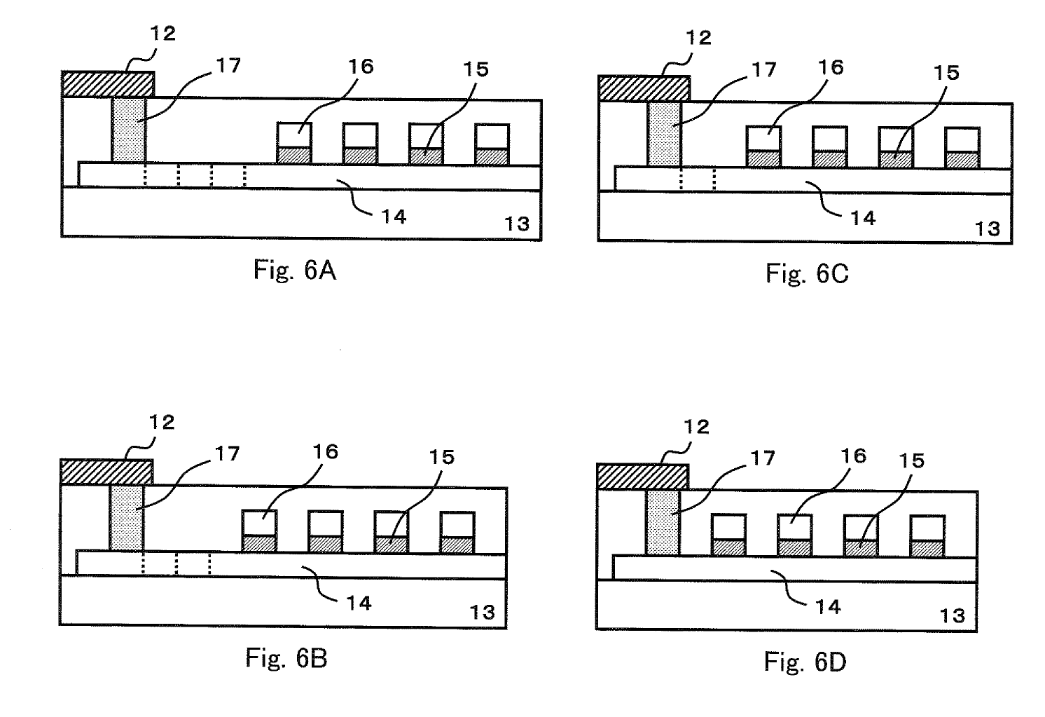

Meanwhile, FIGS. 6A to 6D are schematic sectional views taken along lines S₅-S₅ to S₈-S₈ in FIG. 4. The variable resistor 15 as the memory material is provided between the upper electrode wiring 16 and the lower electrode wiring 14 formed on the base substrate 13, and the lower electrode wiring 14 is connected to the word line decoder (not shown) by a metal wiring 12 through a contact 17. The length of the lower electrode wirings 14 from the end of the cell closest to the word line decoder to the contact 17 are sequentially elongated by the length defined in the formula 6 as shown in FIGS. 6D, 6C, 6B, and 6A, respectively. In addition, the increased lengths of the lower electrode wirings 14 are shown by dotted lines in FIGS. 4 and 6.

According to the second embodiment of the present invention described above, since the load resistor is formed of the same material as that of the upper and lower electrode wirings, the effect described in the first embodiment can be easily attained by a method in which only a layout of the upper electrode wiring and the lower electrode wiring are changed.

In addition, although the upper and lower electrode wirings serving as the load resistors are linearly elongated toward bit line decoder and the word line decoder, respectively in the second embodiment as shown in FIG. 4, the degree of freedom of the layout is not limited to this. For example, in the case of a layout in which the wiring having the longer load resistor may be bent toward the bit line or the word line having the shorter load resistor as needed, the area between the memory cell array and the bit line and word line decoders can be efficiently used.

### Third Embodiment

A semiconductor memory device having a cross-point structure according to a third embodiment of the present invention is specific one means for implementing the 4×4 memory cell array in FIG. 2, similar to the second embodiment.

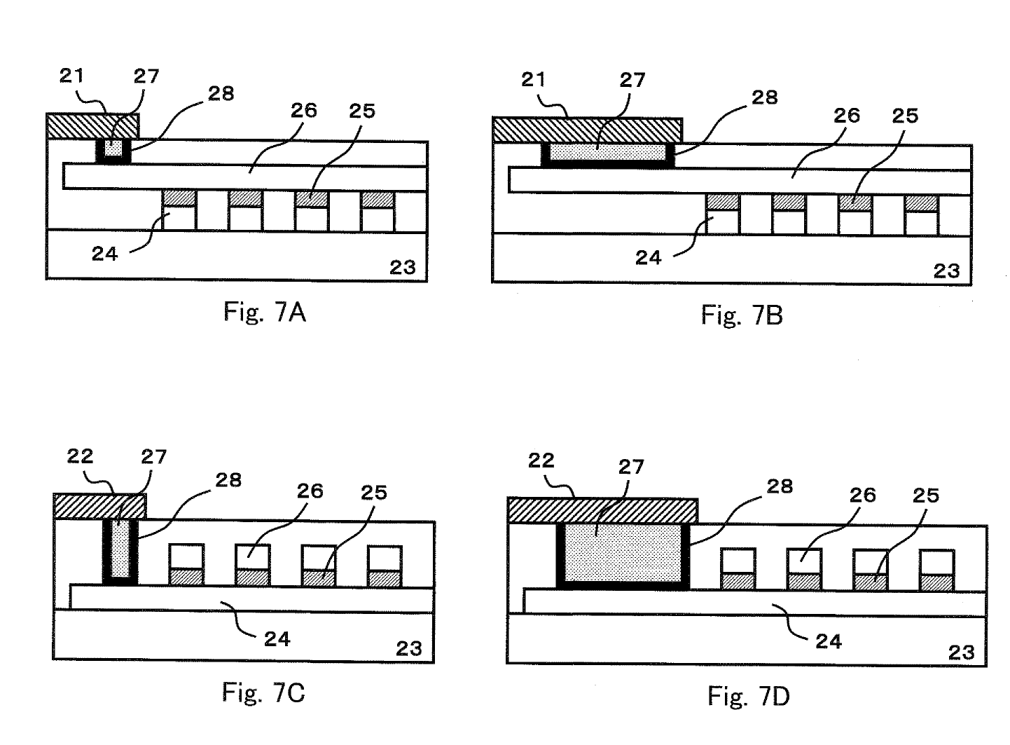

FIG. 7 is a schematic sectional view showing the 4×4 memory cell array shown in FIG. 2, in which FIG. 7A is a schematic sectional view along the bit line B1, and FIG. 7B is a schematic sectional view along the bit line B4. According to this embodiment, similar to the second embodiment, a variable resistor 25 as a memory material is provided between an upper electrode wiring 26 and a lower electrode wiring 24 formed on a base substrate 23, and the upper electrode wiring 26 is connected to a bit line decoder (not shown) by a metal wiring 21 through a contact 27. The base substrate 23 may be a substrate on which a peripheral circuit and the like constituting the semiconductor memory device is formed as needed, and it is preferable that the surface is formed of an insulating film for the lower electrode wirings 24. According to this embodiment, a material having a predetermined resistance value is disposed in the contact 27 and this serves as a load resistor 28. Thus, the resistance values of the load resistors 28 are changed in stages by sequentially changing the size of the contact 27 at the end of the upper electrode wiring 26 from the bit lines B1 to B4. In other words, the bit line B1 disposed closest to the word line decoder has the smallest contact, and the bit line B4 disposed furthest away from the word line decoder has the largest contact.

Similarly, FIG. 7C is a schematic sectional view along the word line W1, and FIG. 7D is a schematic sectional view along the word line W4 in the 4×4 memory cell array shown in FIG. 2. According to this embodiment, similar to the second embodiment, the variable resistor 25 as the memory material is provided between the upper electrode wiring 26 and the lower electrode wiring 24 formed on the base substrate 23, and the lower electrode wiring 24 is connected to the word line decoder (not shown) by a metal wiring 22 through a contact 27. Thus, the resistance values of the load resistors 28 are changed in stages by sequentially changing the size of the contact 27 at the end of the lower electrode wiring 24 from the word lines W1 to W4. In other words, the word line W1 disposed closest to the bit line decoder has the smallest contact, and the word line W4 disposed furthest away from the bit line decoder has the largest contact.

The method for forming the load resistor to implement the first embodiment specifically is not limited to the methods of the second and third embodiments. For example, when the elongated part of the upper electrode wiring or the lower electrode wiring is formed of a material having resistivity higher than that of the upper and lower electrode wirings, the area of the load resistor can be smaller than that in the second embodiment. In addition, the load resistor may be formed of a gate electrode wiring of a peripheral circuit or a wiring using a diffusion layer on the semiconductor substrate.

### Fourth Embodiment

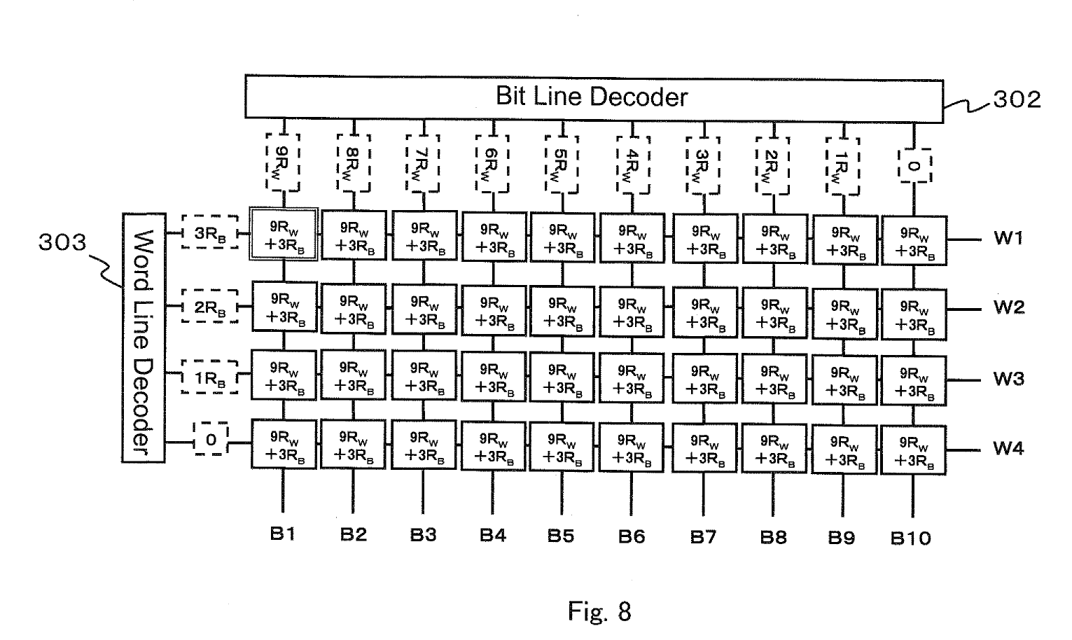

Although the descriptions have been made with the 4×4 simple cell array as the example in which the resistance value of the load resistor is specifically set in the above first to third embodiments, the present invention is not limited to the square matrix memory cell array. For example, as shown in FIG. 8, in the case of a 10×4 rectangular matrix memory cell array, when load resistors 9R_{W}, 8R_{W}, . . . 1R_{W}, 0 are sequentially disposed between a bit line decoder 302 and bit lines B1, B2, . . . , B10, and load resistors 3R_{B}, 2R_{B}, . . . , 0 are sequentially disposed between a word line decoder 303 and word lines W1, W2, . . . , W4, the wiring resistance value of a resistance reference cell at (1, 1) is relatively greater by 9R_{W}+3R_{B} than a case having no load resistor, and the relative increased value of the wiring resistance of any other cell in the memory cell array can be 9R_{W}+3R_{B} similar to the reference cell at (1, 1).

### Fifth Embodiment

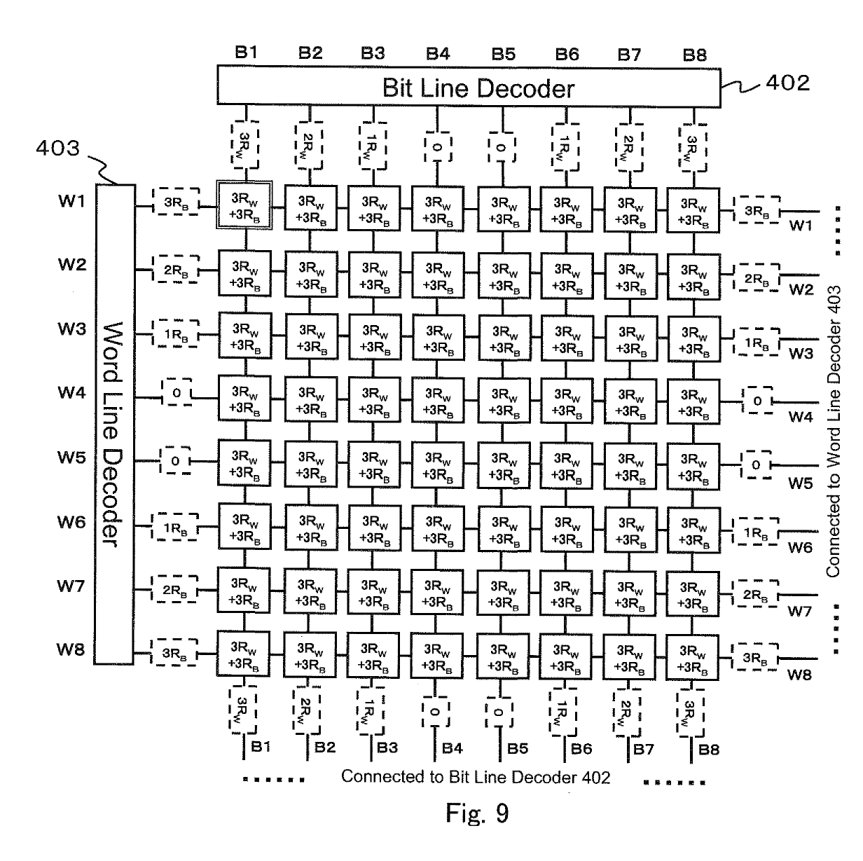

Although descriptions have been made of the case where the bit line and the word line are connected to the bit line decoder and the word line decoder, respectively only from one direction of the memory cell array according to the above-described first to fourth embodiments, the present invention can be applied to the case where they are connected from both sides of the memory cell array in order to reduce lowering of the wiring resistance. That is, as shown in FIG. 9, 8×8 memory cells are provided and bit lines are connected to bit line decoder 402 at both upper and lower sides, and word lines are connected to word line decoder 403 at both right and left sides. Electric connections between the bit line decoder 402 and the bit lines connected to the cells positioned at the intersections with the word lines W1 to W4 are established from the upper side of memory cell array preferentially, and electric connections between the bit line decoder 402 and the bit lines connected to the cells positioned at the intersections with the word lines W5 to W8 are established from the lower side of memory cell array preferentially. Also, electric connections between the word line decoder 403 and the word lines connected to the cells positioned at the intersections with the bit lines B1 to B4 are established from the left side of memory cell array preferentially, and electric connections between the word line decoder 403 and the word lines connected to the cells positioned at the intersections with the bit lines B5 to B8 are established from the right side of memory cell array preferentially. In addition, in this drawing, specific wiring connections from the memory cell array to the bit line decoder 402 and the word line decoder 403 are omitted.

Thus, variable resistors 3R_{W}, 2R_{W}, 1R_{W}, 0, 0, 1R_{W}, 2R_{W}, 3R_{W} are sequentially disposed between the bit line decoder 402 and the bit lines B1 to B8, and variable resistors 3R_{B}, 2R_{B}, 1R_{B}, 0, 0, 1R_{B}, 2R_{B}, 3R_{B} are sequentially disposed between the word line decoder 403 and the word lines W1 to W8, and as a result, the wiring resistance value of a resistance reference cell at (1, 1) is relatively greater by 3R_{W}+3R₅ than a case having no load resistor, and the relative increased value of the wiring resistance of any other cell in the memory cell array can be 3R_{W}+3R_{B} similar to the reference cell at (1, 1).

Although the bit lines are the upper electrode wirings and the word lines are the lower electrode wirings in the above-described first to fifth embodiments, they may be reversed.

In addition, although the numbers of the bit lines and word lines are relatively small such as 4 to 10 in the above first to fifth embodiments, this is for simplifying the description, so that even when the numbers of the bit lines and the word lines are increased to the number of memory cells of a commercially available LSI, the effect of the present invention in which the fluctuation in the wiring resistance of any cell in the memory cell array can be reduced can be implemented by appropriately setting the load resistance value in the same manner as the above description.

In addition, although the load resistors are provided for all the bit lines and the word lines in the above-described first to fifth embodiments, the present invention is not limited to this. For example, when the specific resistance of the first electrode wirings is considerably higher than that of the second electrode wirings (in the case where R_{B}>R_{W}, for example), the load resistors are provided on one side, that is, the side of the second electrode wirings having the low specific resistance to reduce the fluctuation of the wiring resistance of each cell in the memory cell array. In this case, although the relative increase of wiring resistance at each intersection point is not completely uniform in the memory cell array, since the effect of the problematic side of the wiring resistance of the electrode wiring can be compensated, it can be substantially uniform within a small range.

In addition, although the resistance values of the load resistors of the bit lines and the word lines are sequentially changed with respect to each line in the above-described first to fifth embodiments, the present invention is not limited to this. That is, the same load resistor value may be set with respect to each group of lines, or the load resistor may be connected only to the part closer to the bit line decoder or the word line decoder. In this case, although the relative increase of the wiring resistance at each intersection point is not completely uniform in the memory cell array, it can be roughly uniform within a small range, so that the fluctuation of the wiring resistance can be reduced more than that of the conventional semiconductor memory device.

In addition, although there is a problem that an effective voltage applied to the memory material is relatively lower than that of the conventional memory cell array due to voltage drop caused by the load resistor in the above-described first to fifth embodiment, the wiring resistance value at any cell is basically the same as the wiring resistance value at the cell positioned electrically furthest apart from the bit line decoder and the word line decoder in the conventional example, all the cells of the semiconductor memory device in the present invention can be operated at the voltage that ensured the operation of all the cells in the conventional semiconductor memory device. Therefore, according to the present invention, it is not necessary to raise the voltage generated in a voltage pulse generation circuit in particular, and the fluctuation in the effective voltage can be reduced.

Furthermore, although the descriptions have been made based on the fact that voltage drop from the voltage pulse generation circuit to the bit line and the word line through the bit line decoder and the word line decoder is negligibly small in the above-described first to fifth embodiments, even when the voltage drop is not negligible, the sum of the parasitic resistance value from the voltage pulse generation circuit to any intersection point through the first electrode wiring, and the parasitic resistance value from the voltage pulse generation circuit to any intersection point through the second electrode wiring can be roughly constant by setting the resistance value of the load resistor of the present invention so as to compensate the voltage drop, so that the voltage applied to all the cells in the memory cell array can be equal substantially.

In addition, although the descriptions have been made with the RRAM using the variable resistor material whose electric resistance is changed by the application of the voltage as the memory material in the first to fifth embodiments, even when another memory material such as a material having ferroelectric characteristics or a material having ferromagnetic tunneling magneto resistance effect is used, the effectiveness of the present invention is not reduced.

In addition, to reduce the parasitic current in the cross-point structure, a diode may be connected to the cross-point structure part in series in the memory cell. Although the diode is connected to the memory material in series outside the upper electrode or a lower electrode in general, it may be disposed between the memory material and the upper electrode or between the memory material and the lower electrode. The diode is formed of a material showing PN diode characteristics or Schottky diode characteristics, or varistor such as ZnO or Bi₂O₃.

1. A semiconductor memory device having a cross-point structure comprising:
a plurality of first electrode wirings extending in the same direction;
a plurality of second electrode wirings intersecting with the first electrode wirings; and
memory materials for storing data at intersection points of the first electrode wirings and the second electrode wirings, wherein
the sum of a wiring resistance value of the first electrode wiring to a certain intersection point and a wiring resistance value of the second electrode wiring to the certain intersection point substantially shows a constant value at any intersection point.

2. The semiconductor memory device having a cross-point structure according to claim 1, wherein
load resistors for allowing the sum of the wiring resistance value of the first electrode wiring to a certain intersection point and the wiring resistance value of the second electrode wiring to the certain intersection point to show a constant value at any intersection point are connected to at least either one of the plurality of first electrode wirings and the plurality of second electrode wirings.

3. The semiconductor memory device having a cross-point structure according to claim 2, wherein
a memory cell array is formed by disposing the memory materials at the intersection points of the plurality of first electrode wirings and the plurality of second electrode wirings, and
the load resistors are connected to at least either one of the plurality of first electrode wirings and the plurality of second electrode wirings outside the memory cell array.

4. The semiconductor memory device having the cross-point structure according to claim 2, wherein
the load resistors have resistance values sequentially differentiated in stages between the first electrode wirings or the second electrode wirings or both.

5. The semiconductor memory device having the cross-point structure according to claim 4, wherein
resistance values of the load resistors connected to the plurality of first electrode wirings are sequentially differentiated in stages between the load resistors by a value substantially equal to the wiring resistance value of the second electrode wiring across one intersection interval in an extending direction of the second electrode wiring intersecting with the first electrode wiring.

6. The semiconductor memory device having the cross-point structure according to claim 4, wherein
resistance values of the load resistors connected to the plurality of second electrode wirings are sequentially differentiated in stages between the load resistors by a value substantially equal to the wiring resistance value of the first electrode wiring across one intersection interval in an extending direction of the first electrode wiring intersecting with the second electrode wiring.

7. The semiconductor memory device having the cross-point structure according to claim 2, wherein
the load resistor comprises a part of the first electrode wiring or the second electrode wiring.

8. The semiconductor memory device having the cross-point structure according to claim 7, wherein
wiring lengths of the first electrode wirings are differentiated between the first electrode wirings, or wiring lengths of the second electrode wirings are differentiated between the second electrode wirings.

9. The semiconductor memory device having the cross-point structure according to claim 8, wherein
when it is assumed that the number of the first electrode wirings is M, wherein M is a natural number, a length of one intersection interval in an extending direction of the first electrode wiring is L₁, a wiring resistance value of the first electrode wiring across one intersection interval is R_{B}, a wiring resistance value of the second electrode wiring across one intersection interval in an extending direction of the second electrode wiring is R_{W}, the wiring lengths of the plurality of first electrode wirings are sequentially differentiated in stages between the first electrode wirings by a length of (m−1)×L₁×(R_{W}/R_{B}), wherein m=1, 2, 3, . . . , M.

10. The semiconductor memory device having the cross-point structure according to claim 8, wherein
when it is assumed that the number of the second electrode wirings is N, wherein N is a natural number, a length of one intersection interval in an extending direction of the second electrode wiring is L₂, a wiring resistance value of the second electrode wiring across one intersection interval is R_{W}, a wiring resistance value of the first electrode wiring across one intersection interval in an extending direction of the first electrode wiring is R_{B}, the wiring lengths of the plurality of second electrode wirings are sequentially differentiated in stages between the second electrode wirings by a length of (n−1)×L₂×(R_{B}/R_{W}), wherein n=1, 2, 3, . . . , N.

11. A semiconductor memory device having a cross-point structure comprising:
a memory cell array having a cross-point structure having a plurality of first electrode wirings extending in the same direction, a plurality of second electrode wirings intersecting with the first electrode wirings, and memory materials for storing data at intersection points between the first electrode wirings and the second electrode wirings;
a bit line decoder, a word line decoder, and a voltage pulse generation circuit for applying an operation voltage to a certain memory cell in the memory cell array; and
load resistors connected to at least either one of the first electrode wirings and the second electrode wirings and having resistance values differentiated sequentially in stages between the first electrode wirings or the second electrode wirings or both, wherein
the load resistors allow the sum of a parasitic resistance value from the voltage pulse generation circuit to a certain intersection point through the first electrode wiring and a parasitic resistance value from the voltage pulse generation circuit to the certain intersection point through the second electrode wiring to show a substantially constant value at any intersection point.

12. The semiconductor memory device having the cross-point structure according to claim 1, wherein
the memory material for storing data has ferroelectric characteristics.

13. The semiconductor memory device having the cross-point structure according to claim 1, wherein
the memory material for storing data has ferromagnetic tunneling magneto resistance effect.

14. The semiconductor memory device having the cross-point structure according to claim 1, wherein
the memory material for storing data is formed of a variable resistor material.

15. The semiconductor memory device having the cross-point structure according to claim 11, wherein
the memory material for storing data has ferroelectric characteristics.

16. The semiconductor memory device having the cross-point structure according to claim 11, wherein
the memory material for storing data has ferromagnetic tunneling magneto resistance effect.

17. The semiconductor memory device having the cross-point structure according to claim 11, wherein
the memory material for storing data is formed of a variable resistor material.
